(19) United States
(12) Patent Application Publication
(10) Pub. No.: US 2008/0157299 A1
(43) Pub. Date: Jul. 3, 2008

(54) Microelectronic Assembly Using Chip-On-Lead (COL) and Cantilever Leads

(76) Inventors: Jeffery Gail Holloway, Plano, TX (US); Anthony L. Coyle, Plano, TX (US)

Correspondence Address: TEXAS INSTRUMENTS INCORPORATED, P O BOX 655474, M/S 3999, DALLAS, TX, 75265, US

(21) Appl. No.: 11/617,504

(22) Filed: Dec. 28, 2006

(51) Int. Cl. H01L 23/495; H01L 21/60

(52) U.S. Cl. 257/670; 438/107; 257/E21.506; 257/E23.043

(57) ABSTRACT

Packaged microelectronic semiconductor devices and methods for their assembly are described. According to preferred embodiments of the invention, chip-on-lead techniques are adapted to provide chip-on-lead packages using cantilevered leads. Exemplary embodiments of the invention include methods using a temporary brace to support the cantilevered leads during chip mounting. Versatile chip package embodiments are disclosed including those in which the chip mounting pad is smaller than the chip(s) mounted thereupon, and further examples wherein the chip mounting pad is dispensed with and a chip is mounted on the cantilevered leads alone.

### TECHNICAL FIELD

The invention relates to electronic semiconductor devices and manufacturing. More particularly, the invention relates to microelectronic semiconductor device package assemblies employing leadframes with cantilevered leads, and to methods for making chip-on-lead (COL) assemblies with cantilevered leads.

### BACKGROUND OF THE INVENTION

Microelectronic semiconductor device packages are subject to maximum size constraints at the system level, and minimum size constraints based on the semiconductor die, or chip, size. Of course, no package can be smaller than the chip itself. The maximum size of a chip that fits in a particular package varies with the package style. The leadframe provides mechanical support to the chip during its assembly into a finished product. Typically, the leadframe consists of a mounting pad, to which the chip is attached, and leads, which serve as the means for external electrical connection to the world outside the chip. The typical package is made by mounting a chip on an exposed mounting pad, leaving a necessary gap between the leads and the mounting pad. The planar area of the chip is generally less than that of the mounting pad by an amount determined by various manufacturing and reliability concerns. There is often also a minimum chip size for a given mounting pad size because the wires that extend from the chip to the leads must be limited in length for reasons of manufacturability and/or electrical performance. Since there is usually little flexibility in terms of combining mounting pads and chips of different sizes, typically a series of leadframes with various mounting pad sizes must be provided for use with various chip sizes.

In order to keep the bond wires that stretch from chip to lead short, cantilevered leads are known in the arts. Cantilevered leads, as heretofore practiced in the arts, are leads which project from the periphery of the leadframe inward toward a mounting pad location in the central region of the leadframe. A relatively small mounting pad designed for supporting a small chip is the norm. Significantly different chip sizes therefore require different leadframe designs with different cantilever lead lengths, each design requiring its own tooling and separate stocking. This lack of flexibility places practical cost limitations on the implementation of devices employing cantilevered leads.

Supporting the chip on the leads, called chip-on-lead or COL, is another design approach known in the arts. Chip-on-lead designs have historically been limited by the requirement that the leads be capable of withstanding the stresses generated by the chip attachment process. Generally, molded plastic packages using a COL design are limited to types that have full lead thicknesses, and not cantilevered leads, which typically have a thinner, partial-thickness inner portion. This is because, using common assembly processes, when the chip is pressed onto the leads, full thickness leads are supported from below across their whole area by the flat surface on which they are placed. Thus, the force of placing the chip on the leads is resisted by the full-thickness leads, whereas partial-thickness, cantilevered leads would have a tendency to bend. The cantilever leads used in the so-called leadless molded package type are not supported by an underlying flat surface. In most cases, the leads are not rigid enough to avoid bending when subjected to pressure during chip mounting processes.

Due to these and other technical challenges, improved packaged chip-on-lead (COL) semiconductor device assemblies and methods for their manufacture would be useful and advantageous in the arts. The present invention is directed to overcoming, or at least reducing the effects of, one or more of the problems described above.

### SUMMARY OF THE INVENTION

In carrying out the principles of the present invention, in accordance with preferred embodiments thereof, packaged microelectronic semiconductor devices and methods for their assembly use cantilevered leads in a chip-on-lead configuration. The cantilevered leads extend from the periphery of a leadframe toward a central region where a chip is affixed directly to the cantilevered leads. Temporary bracing preferably supports the cantilevered leads during chip mounting when needed.

According to one aspect of the invention, a method for assembling a packaged microelectronic semiconductor device includes steps of providing a leadframe that has numerous cantilevered leads extending from the periphery toward a central region. A chip is affixed to the central region of the leadframe on a plurality of the cantilevered leads.

According to another aspect of the invention, according to a preferred embodiment, a method for assembling a packaged semiconductor device also includes the step of providing tie bars extending from the outer corners of the leadframe supporting a mounting pad located in the central region of the leadframe. A chip is affixed to both the mounting pad and to a plurality of the cantilevered leads.

According to yet other aspects of the invention, in preferred embodiments, steps include the attachment of multiple chips to the mounting pad and cantilevered leads.

According to another aspect of the invention, a microelectronic semiconductor device package assembly has a leadframe with a plurality of cantilevered leads extending from the periphery of the package toward a central region and a chip attached to the cantilevered leads.

According to another aspect of the invention, a package assembly according to preferred embodiments has more than one chip affixed to cantilevered leads in the central region of a leadframe.

According to another aspect of the invention, a microelectronic semiconductor device package assembly includes a leadframe having tie bars supporting a mounting pad in the central region of the leadframe. The mounting pad is smaller in area than the chip, and is adjacent to cantilevered leads. One or more chips are affixed both to the mounting pad and to a number of the cantilevered leads.

The invention has numerous advantages including but not limited to providing methods and packaged semiconductor device assemblies offering one or more of the following; accommodating the use of a single leadframe for multiple die sizes while allowing similar wire lengths for the multiple die sizes, improved efficiency in the assembly process, and reduced costs. These and other features, advantages, and benefits of the present invention can be understood by one of ordinary skill in the arts upon careful consideration of the detailed description of representative embodiments of the invention in connection with the accompanying drawings.

### BRIEF DESCRIPTION OF THE DRAWINGS

The present invention will be more clearly understood from consideration of the following detailed description and drawings in which:

FIG. 1 is a top view of an example of a preferred embodiment of a leadframe according to the invention;

FIG. 2 is a top view of an example of a preferred embodiment of a chip mounted on a leadframe configured as shown in FIG. 1;

FIG. 3 is a side view of an example of a preferred embodiment of a semiconductor package having a leadframe and chip configured as shown in FIG. 2; and

FIG. 4 is a top view of another example of a preferred embodiment of a leadframe according to the invention;

FIG. 5 is a top view of an example of a preferred embodiment of a chip mounted on a leadframe configured as shown in FIG. 4;

FIG. 6 is a side view of an example of a preferred embodiment of a semiconductor package having a leadframe and chip configured as shown in FIG. 5; and

FIG. 7 is a top view of an example of another preferred embodiment of a plurality of chips mounted on a leadframe in accordance with the invention.

References in the detailed description correspond to like references in the various Figures unless otherwise noted. Descriptive and directional terms used in the written description such as first, second, top, bottom, upper, side, etc., refer to the drawings themselves as laid out on the paper and not to physical limitations of the invention unless specifically noted. The drawings are not to scale, and some features of embodiments shown and discussed are simplified or amplified for illustrating the principles, features, and advantages of the invention.

### DETAILED DESCRIPTION OF PREFERRED EMBODIMENTS

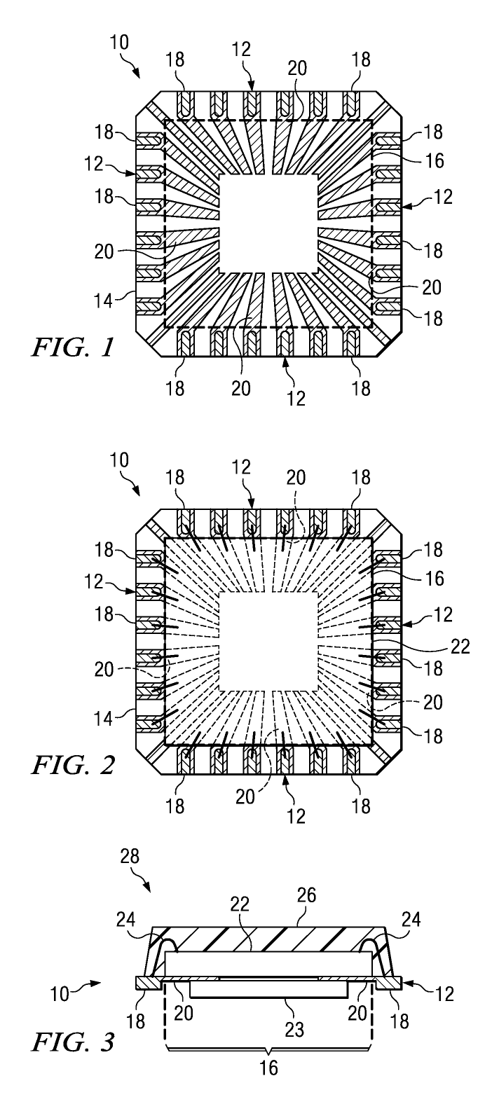

In general, the invention provides packaged microelectronic semiconductor devices and methods for their assembly using cantilevered leads in a chip-on-lead configuration. Referring primarily to FIG. 1, a leadframe 10 is shown in accordance with a preferred embodiment of the invention. Cantilevered leads 12 extend from the periphery 14 of the leadframe 10 toward a central region 16. The cantilevered leads 12 preferably have full-thickness metal portions 18 and partial-thickness metal portions 20, sometimes referred to as “half-metal” in the art, although they are frequently not precisely half of the thickness of the “full-metal”. The full-thickness metal portions 18 preferably have a terminus at the periphery 14 of the leadframe 10, giving way to the partial-thickness metal portions 20 further inward, toward the central region 16. Preferably, the partial-metal portions 20 terminate in the central region 16. As shown in the top view of FIG. 2, and the corresponding side view of FIG. 3, a chip 22 may preferably be affixed to the central region 16 of the leadframe 10. As can be seen in FIGS. 2 and 3, the chip 22 is preferably supported by the partial-metal portions 20 of the cantilevered leads 12. Those familiar with the art will recognize that the configuration shown and described may be used to accommodate chips of various aspect ratios and sizes without modification of the leadframe. Preferably, the chip 22, wirebonds 24, and most of the leadframe 10, are ultimately encapsulated in a dielectric mold compound 26 in order to form a completed semiconductor device package 28.

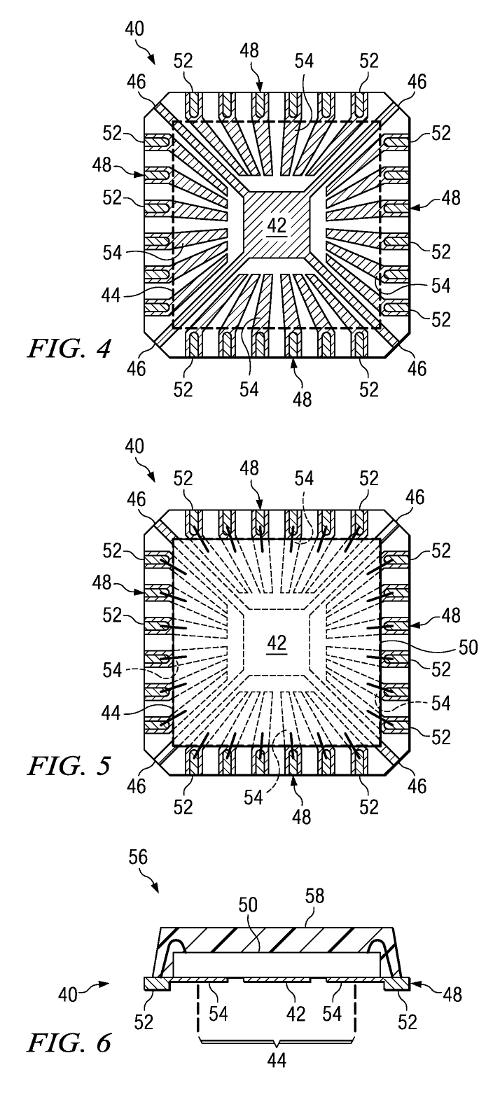

Now referring primarily to FIG. 4, an example of an alternative embodiment of the invention has a leadframe 40 on which a mounting pad 42 spans at least a portion of the central region 44. The mounting pad 42 is preferably supported by tie bars 46 extending from the leadframe 40 corners. As in the other examples herein, cantilevered leads 48 extend from the periphery of the leadframe 40 to the central region 44. It can be seen that the cantilevered leads 48 do not connect with the mounting pad 42. A chip 50, shown in the top view of FIG. 5 and corresponding side view of FIG. 6, may be affixed to the leadframe 40, preferably supported, at least in part, by the cantilevered leads 48 in the central region 44 of the leadframe 40. Additional support for the chip 50 may be provided by the mounting pad 42. It should be appreciated that a chip larger in planar area than the mounting pad may be used, since it may be supported by the cantilevered leads extending into the central region of the leadframe. Preferably, the cantilevered leads 48 include a full-metal portion 52 at their outer ends, and a partial-metal portion 54 at their inner ends. The partial-metal portions 54 preferably support the chip 50. As with the embodiment described above, a protective package 56 is preferably formed by encapsulating the chip 50 and leadframe 40 in mold compound 58 as known in the packaging art.

In some instances, in preferred methods of assembling a COL package on cantilevered leads in accordance with the invention, a temporary brace may be used under the cantilevered leads. Again referring primarily to FIG. 3, a configuration is shown in which the cantilevered leads 12 have a partial-thickness metal portion 20 supporting the chip 22. During chip 22 attachment, a brace 23 may preferably be inserted beneath the central region 16 of the leadframe 10 in order to support the partial-metal portion 20 of the cantilevered leads 12. The exact configuration of the brace is not crucial to the practice of the invention so long as it is adapted to provide support to the partial-thickness portions of the cantilevered leads during chip attachment. For example, in an arrangement of opposing parallel cantilevered leads on an array of leadframes prepared for receiving chips, as in a Dual In-line Package (DIP), a removable rail may be used as a brace beneath the partial-thickness portion of the leads. After chip attachment, preferably using nonconductive adhesive known in the arts for COL assemblies, the brace may be withdrawn. In another example of a common configuration, with cantilevered leads arranged in a radial pattern about a central region, (as shown in the leadframes of FIGS. 1 and 4) a central pillar may be placed beneath the central region during chip attachment, supporting the leadframe to withstand the stress of chip placement, and withdrawn thereafter.

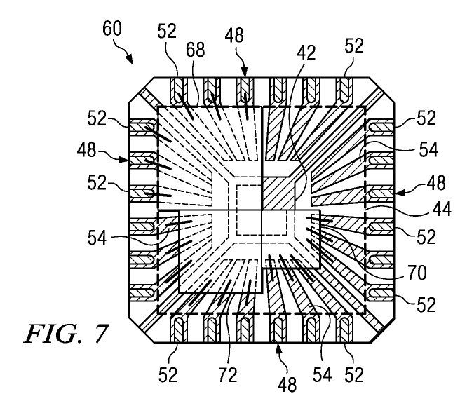

Another example of a preferred embodiment of the invention is shown in FIG. 7. A leadframe 60 having cantilevered leads 48 and a mounting pad 42 in a central region 44 is shown in this top view. Multiple chips 68, 70, 72, are mounted on the central region 44 of the leadframe 40, preferably in a manner similar to that shown and described with reference to the other embodiments herein. The chips 68, 70, 72, are preferably supported by the mounting pad 42 and the cantilevered leads 48 as illustrated, demonstrating the flexibility of the leadframe 60 for use with different aspect ratios, sizes, and numbers of chips.

The invention provides advantages including but not limited to one or more of the following: permitting the mounting of chips larger in area than the maximum possible pad size in any given package size, allowing a greater range of chip sizes to be used with a given leadframe; permitting a reduction in the chip mounting pad area required for packaging associated IC components; increasing assembly and design process efficiency; and, reducing costs. While the invention has been described with reference to certain illustrative embodiments, the methods and systems described are not intended to be construed in a limiting sense. Various modifications and combinations of the illustrative embodiments as well as other advantages and embodiments of the invention will be apparent to persons skilled in the art upon reference to the description and claims.

We claim:

1. A method for assembling a microelectronic semiconductor device comprising the steps of:
providing a leadframe having a plurality of cantilevered leads extending from a periphery toward a central region; and
affixing a microelectronic semiconductor chip to a plurality of the cantilevered leads in the central region of the leadframe.

2. A method for assembling a microelectronic semiconductor device according to claim 1 wherein the cantilevered leads are provided with a partial-thickness portion in the central region, and wherein the chip is affixed to the partial-thickness portion of cantilevered leads in the central region of the leadframe.

3. A method for assembling a packaged microelectronic semiconductor device according to claim 1 wherein the cantilevered leads are provided with a partial-thickness portion in the central region, and wherein the chip is affixed to the partial-thickness portion of cantilevered leads in the central region of the leadframe, further comprising the steps of;
providing a brace in support of the partial-thickness portion of a plurality of the cantilevered leads during the step of affixing a chip to the cantilevered leads; and,
removing the brace subsequent to the affixing the chip to the cantilevered leads.

4. A method for assembling a packaged microelectronic semiconductor device according to claim 1 further comprising the step of affixing one or more additional chips to a plurality of the cantilevered leads in the central region of the leadframe.

5. A method for assembling a packaged microelectronic semiconductor device according to claim 1 further comprising the steps of:
providing tie bars extending from the corners of the periphery of the leadframe toward the central region of the leadframe;
providing a mounting pad in the central region of the leadframe supported by the tie bars; and,
affixing at least one chip to the mounting pad and to a plurality of the cantilevered leads in the central region of the leadframe.

6. A method for assembling a packaged microelectronic semiconductor device according to claim 1 further comprising the steps of:
providing tie bars extending from the corners of the periphery of the leadframe toward the central region of the leadframe;
providing a mounting pad in the central region of the leadframe supported by the tie bars; and,
affixing one or more chips to the mounting pad and to a plurality of the cantilevered leads in the central region of the leadframe, wherein the one or more chips are larger in area than the mounting pad.

7. A method for assembling a packaged microelectronic semiconductor device according to claim 1 wherein the cantilevered leads are provided with a partial-thickness portion in the central region, and wherein one or more chips are affixed using nonconductive adhesive to the partial-thickness portion of cantilevered leads in the central region of the leadframe.

8. A packaged microelectronic semiconductor device assembly comprising:
a leadframe having a plurality of cantilevered leads extending from the periphery of the package toward a central region; and
one or more chips affixed in the central region to a plurality of the cantilevered leads.

9. A packaged microelectronic semiconductor device assembly according to claim 8 further comprising:
tie bars extending from the corners of the periphery of the package toward the central region of the leadframe; and,
a mounting pad in a portion of the central region of the leadframe, the mounting pad supported by the tie bars; wherein,
the one or more chips are affixed in the central region of the leadframe to both the mounting pad and to a plurality of the cantilevered leads.

10. A packaged microelectronic semiconductor device assembly according to claim 8 further comprising nonconductive adhesive for affixing the one or more chips to the cantilevered leads.

11. A packaged microelectronic semiconductor device assembly according to claim 8 wherein the leadframe further comprises tie bars extending from the corners of the periphery of the package toward the central region of the leadframe; and wherein,
the leadframe further comprises a mounting pad; wherein,
two or more chips are affixed to both the mounting pad and to a plurality of the cantilevered leads; wherein
the mounting pad is smaller in area than the combined area of the two or more chips.

12. A packaged microelectronic semiconductor device assembly according to claim 8 wherein the package further comprises a Quad Flat No-lead (QFN) package.

13. A packaged microelectronic semiconductor device assembly according to claim 8 wherein the package further comprises a Small Outline No-lead (SON) package.
